(19) United States
(12) Patent Application Publication
(10) Pub. No.: US 2014/0160687 A1
(43) Pub. Date: Jun. 12, 2014

(54) ELECTRONIC DEVICE ENCLOSURE

(71) Applicants: HON HAI PRECISION INDUSTRY CO., LTD., New Taipei (TW); HONG FU JIN PRECISION INDUSTRY (ShenZhen) CO., LTD ., Shenzhen (CN)

(72) Inventors: XIU-QUAN HU, Shenzhen (CN); YU-WEI HE, Shenzhen (CN)

(73) Assignees: HONG FU JIN PRECISION INDUSTRY (ShenZhen) CO., LTD ., Shenzhen (CN); HON HAI PRECISION INDUSTRY CO., LTD., New Taipei (TW)

(21) Appl. No.: 13/972,223

(22) Filed: Aug. 21, 2013

(30) Foreign Application Priority Data
Dec. 6, 2012 (CN) 2012105180590

(51) Int. Cl. H05K 5/02

(52) U.S. Cl. CPC H05K 5/0217
USPC 361/727

(57) ABSTRACT

An enclosure for an electronic device includes a sliding groove, a handle, and a restricting member. The sliding groove includes a wide portion and a narrow portion. The handle includes a clasp. The restricting member is secured on the handle. The restricting member includes a stopping piece. The clasp is inserted into the wide portion and slides to the narrow portion to engage on the enclosure. The stopping piece is placed in the wide portion and abut an edge of the wide portion.

### BACKGROUND

1. Technical Field

The present disclosure relates to an electronic device enclosure.

2. Description of Related Art

Electronic device enclosures generally are not easy to lift or to hold onto when the electronic device is being transported. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device enclosure according to one embodiment.

FIG. 2 is an exploded, isometric view of an enclosure and a handle of the

FIG. 3 is similar to FIG. 2, but viewed from another aspect.

FIG. 4 is a first assembled view of the enclosure and the handle of FIG. 2.

FIG. 5 is a second assembled view of the enclosure and the handle of FIG. 2.

FIG. 6 is a third assembled view of the enclosure and the handle of FIG. 2.

FIG. 7 is a fourth assembled view of the enclosure and the handle of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

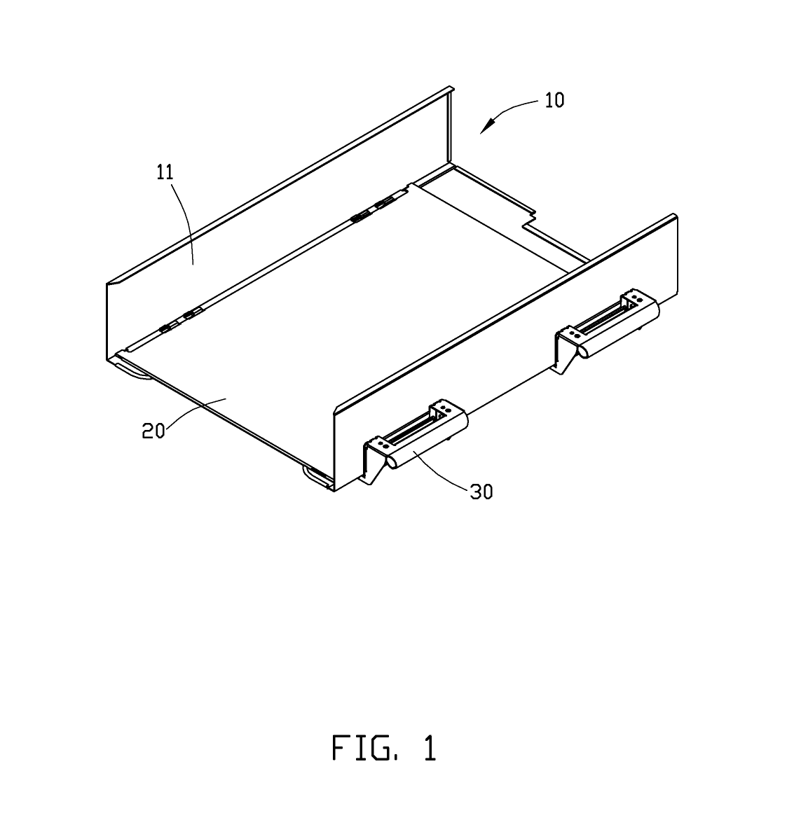

FIG. 1 shows an embodiment of an electronic device enclosure 10. The electronic device enclosure 10 includes a bottom plate 20 and a pair of side plates 11 perpendicularly connected to opposite edges of the bottom plate 20. Each of the pair of side plate 11 is equipped with two handles 30.

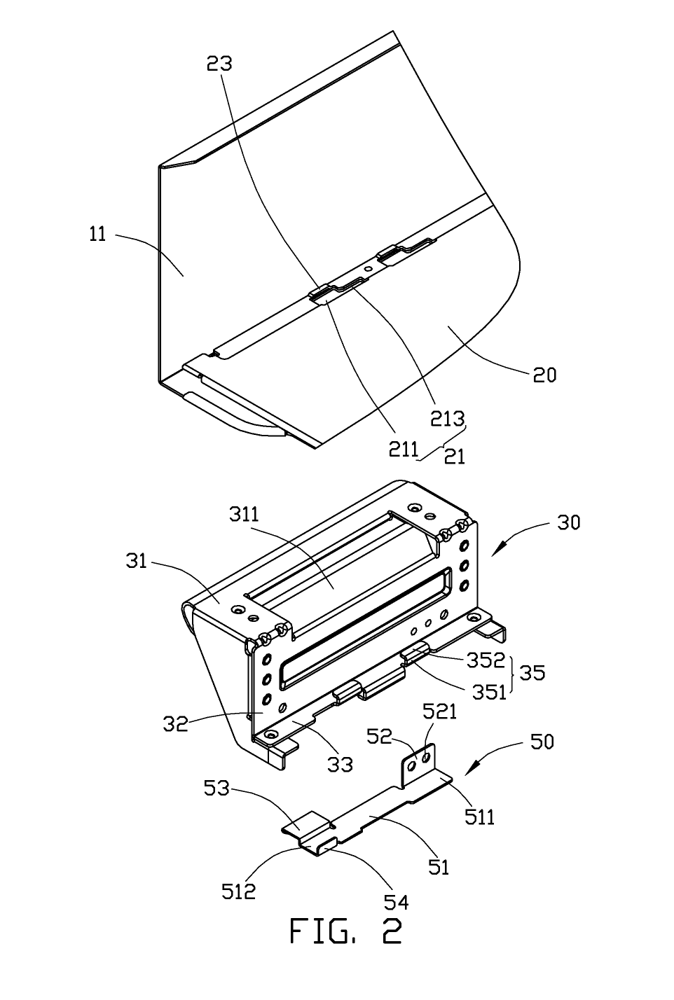

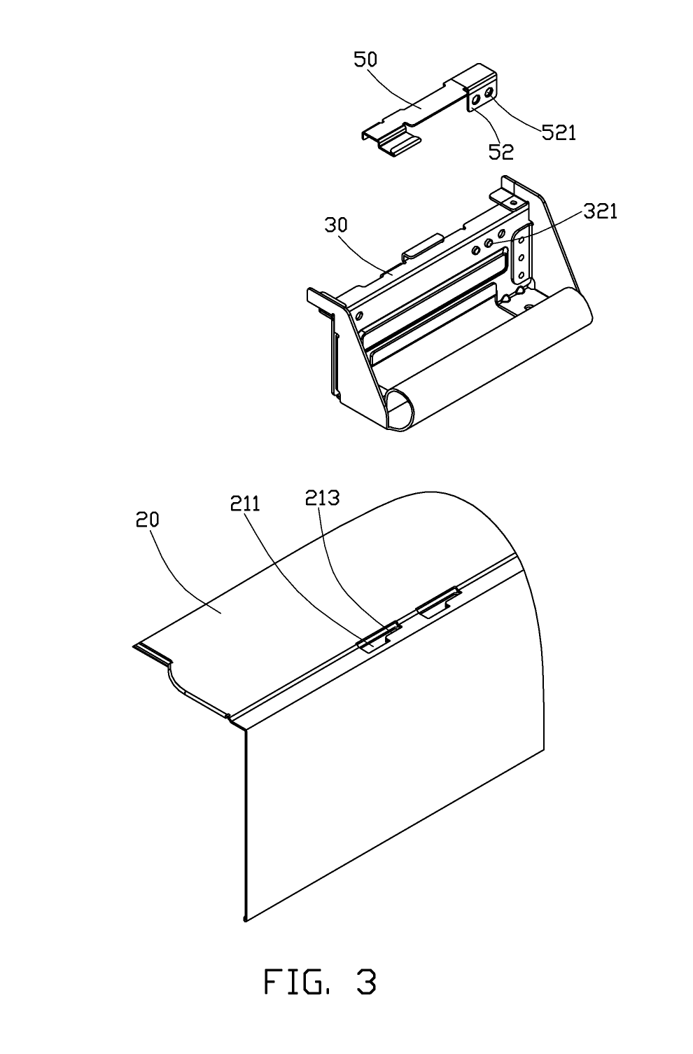

Referring to FIGS. 2 and 3, the bottom plate 20 defines a pair of mounting grooves 21. Each mounting groove 21 includes a wide portion 211 and a narrow portion 213 in communication with the wide portion 211. The bottom plate 20 forms a supporting piece 23 adjacent to each wide portion 211. The supporting piece 23 protrudes onto the bottom plate 20.

The handle 30 includes a lifting piece 31 and a connecting piece 32 perpendicularly connected to the lifting piece 31. The lifting piece 31 defines a receiving opening 311. A bottom edge of the connecting piece 32 extends perpendicularly to form a securing piece 33. The securing piece 33 is parallel to the lifting piece 31. A pair of clasps 35 is connected on the securing piece 33. Each clasp 35 includes a sliding portion 351 and an engaging portion 352. The sliding portion 351 is perpendicularly connected to the securing piece 33. The engaging portion 352 is perpendicularly connected to the sliding piece 351. A plurality of posts 321 is connected on the connecting piece 32. The plurality of posts 321 and the securing piece 33 extend in opposite directions.

A restricting member 50 is mountable on the handle 30. The restricting member 50 includes a main portion 51 which can be elastically bent. The main portion 51 includes a first end 511 and a second end 512. A mounting piece 52 is perpendicularly connected to the first end 511. The mounting piece 52 defines two mounting holes 521. A pulling piece 53 and a stopping piece 54 are connected to the second end 512. The stopping piece 54 faces the pulling piece 53. A height of the stopping piece 54 is substantially equal to a height of the supporting piece 23. The pulling piece 53 can be pulled to elastically bend the main portion 51 to move the stopping piece 54.

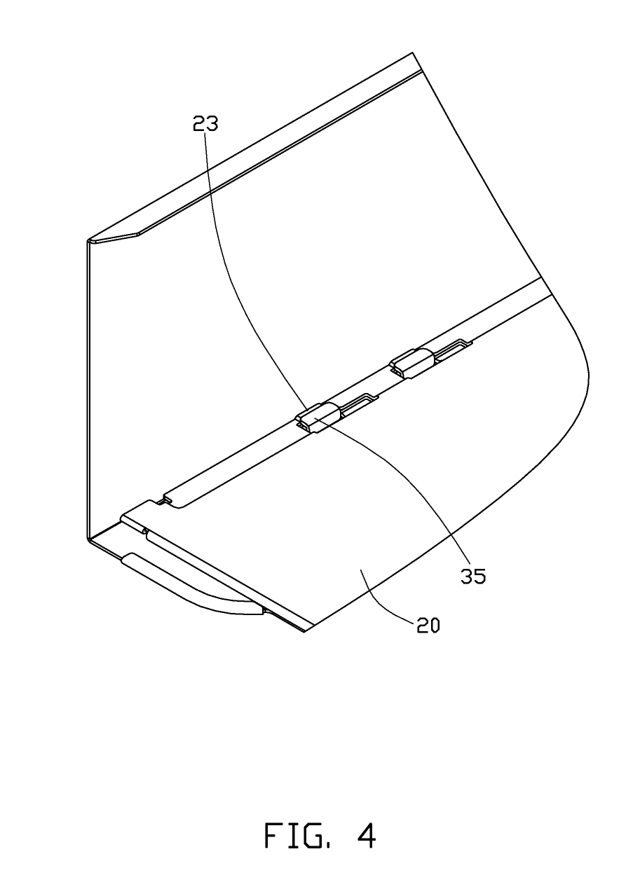

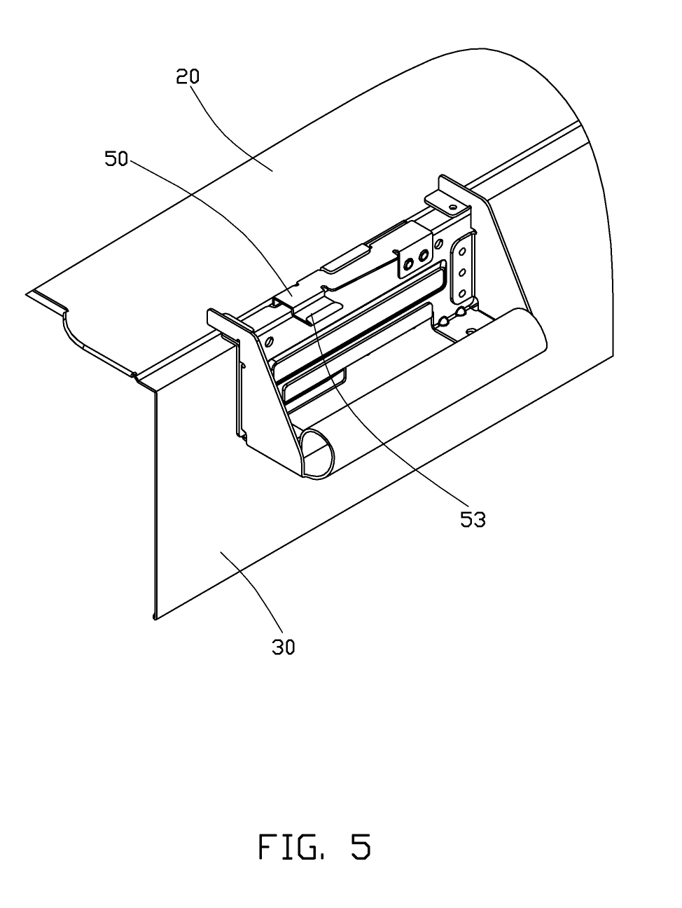

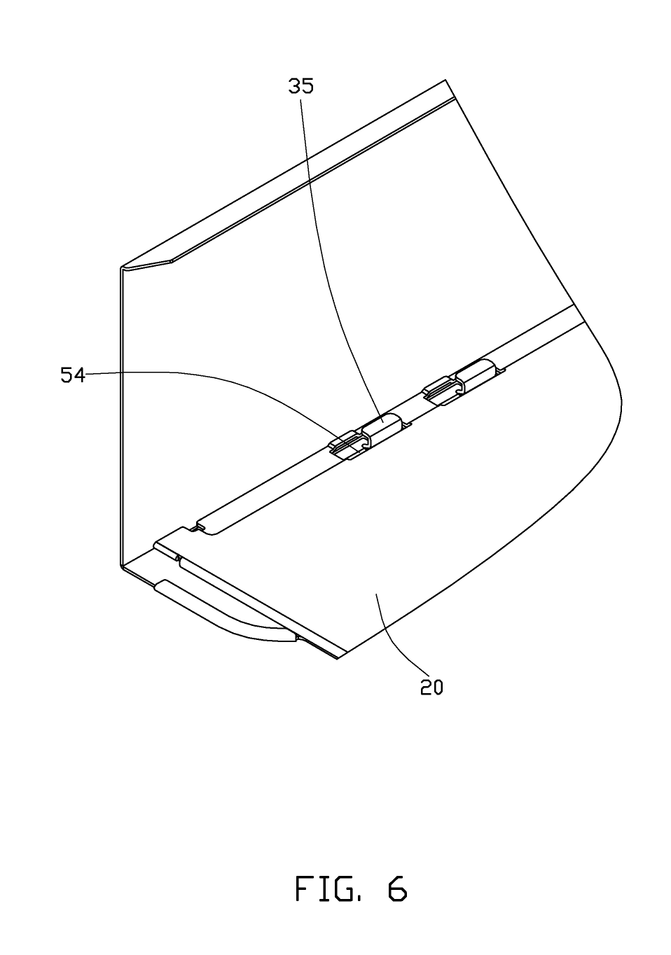

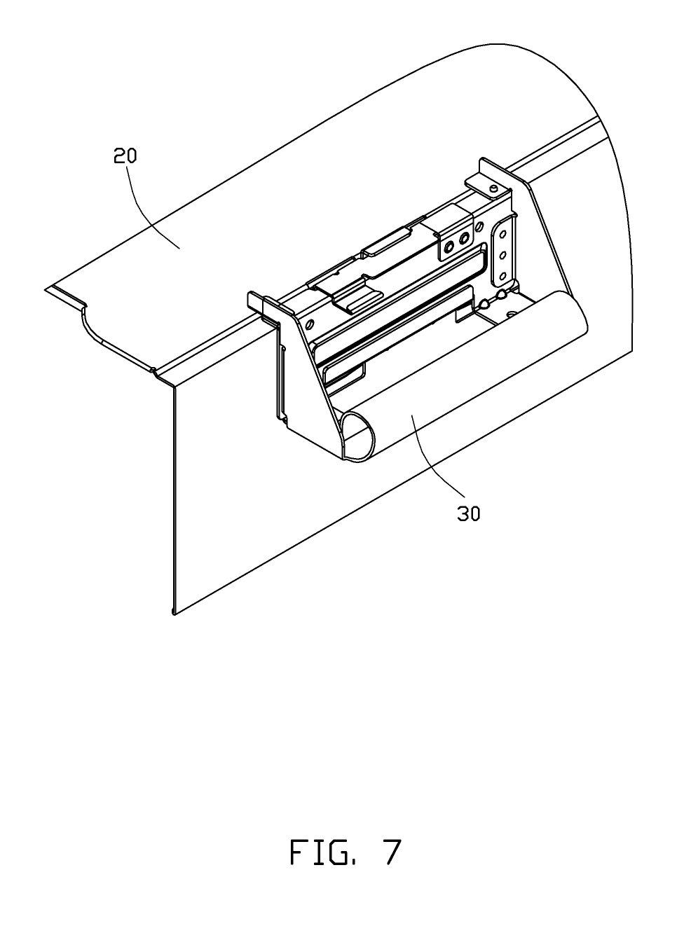

Referring to FIGS. 1 to 7, in assembly, the post 321 of the connecting piece 32 is inserted in the mounting holes 521 of the mounting piece 52 to secure the restricting member 50 on the handle 30. Then, the engaging portion 352 of the clasp 35 of the handle 30 is inserted through the wide portion 211 of the mounting groove 21. The sliding portion 351 of the clasp 35 is located in the wide portion 211. At this position, the engaging portion 352 is located on the supporting piece 23, and the stopping piece 54 abuts a bottom side of the bottom plate 20.

Then, the sliding portion 351 slides in the mounting groove 21 from the wide portion 211 to the narrow portion 213. The engaging portion 352 slides down the supporting piece 23 to be engaged on the bottom plate 20. The stopping piece 54 is aligned to the wide portion 211 of the mounting groove 21. In succession, the stopping piece 54 rebounds to be inserted in the wide portion 211. The stopping piece 54 abuts an edge of the wide portion 211 to prevent the handle 30 from sliding back. Thereby, the handle 30 is mounted on the enclosure 10.

Therefore, the enclosure 10 can be conveniently moved by a hand inserted in the receiving opening 311.

When the handle 30 needs to be detached, the pulling piece 53 is pulled to move the stopping piece 54 out of the mounting groove 21. The stopping piece 54 then does not abut the edge of the wide portion 211 of the mounting groove 21. The sliding portion 351 of the clasp 35 slides from the narrow portion 213 back to the wide portion 211. The clasp 35 can then be moved out of the wide portion 211 to detach the handle 30 from the enclosure 10.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device enclosure, comprising:
a sliding groove defined in the electronic device enclosure, the sliding groove comprising a wide portion and a narrow portion;
a handle comprising a clasp; and
a restricting member secured on the handle, the restricting member comprising a stopping piece;
wherein the clasp is configured to be inserted into the wide portion and slide to the narrow portion to engage on the enclosure, and the stopping piece is configured to be placed in the wide portion and abut an edge of the wide portion when the clasp is in the narrow portion.

2. The electronic device enclosure of claim 1, wherein the restricting member comprises a flexible main portion, the flexible main portion comprises a first end, a mounting piece is connected on the first end, and the mounting piece is secured on the handle.

3. The electronic device enclosure of claim 2, wherein the flexible main portion comprises a second end on which the stopping piece is connected, a pulling piece is connected to the second end, and the pulling piece is adapted to be pulled to elastically move the flexible main portion to move the stopping piece.

4. The electronic device enclosure of claim 1, wherein the clasp comprises a sliding portion and an engaging portion, the engaging portion is configured to be inserted through the wide portion, the sliding portion is configured to slide from the wide portion to the narrow portion to move the engaging portion to engage on the enclosure.

5. The electronic device enclosure of claim 4, wherein the enclosure comprises a supporting piece adjacent the wide portion, the supporting piece protrudes on the enclosure, the engaging portion is configured to be placed on the supporting piece to move the stopping piece to abut the enclosure and to elastically bend the stopping piece.

6. The electronic device enclosure of claim 5, wherein a height of the stopping piece is substantially equal to a height of the supporting piece.

7. The electronic device enclosure of claim 1, wherein the handle comprises a lifting piece in which a receiving opening is defined.

8. The electronic device enclosure of claim 7, wherein a connecting piece is connected to the lifting piece, and a securing piece is connected to the connecting piece, and the clasp protrudes on the securing piece.

9. The electronic device enclosure of claim 8, wherein the securing piece is parallel to the connecting piece.

10. An electronic device enclosure, comprising:
a sliding groove defined in the electronic device enclosure, the sliding groove comprising a wide portion and a narrow portion, a supporting piece being formed on the enclosure and adjacent the wide portion; and
a handle comprising a clasp and a stopping piece, the clasp comprising a sliding portion and an engaging portion, wherein the engaging portion is configured to be inserted through the wide portion to engage the supporting piece to move the stopping piece to abut the enclosure and to elastically bend the stopping piece, and the sliding portion is configured to slide from the wide portion to the narrow portion and to move the stopping piece into the wide portion.

11. The electronic device enclosure of claim 10, wherein the stopping piece is configured to abut an edge of the wide portion when the stopping piece is in the wide portion.

12. The electronic device enclosure of claim 11, wherein a restricting member is mounted on the handle, the clasp is connected on the restricting member, the restricting member comprises a flexible main portion, the flexible main portion comprises a first end, a mounting piece is connected on the first end, and the mounting piece is secured on the handle.

13. The electronic device enclosure of claim 12, wherein the flexible main portion comprises a second end on which the stopping piece is connected, a pulling piece is connected to the second end, and pulling piece is adapted to be pulled to elastically move the main portion to move the stopping piece.

14. The electronic device enclosure of claim 10, wherein a height of the stopping piece is substantially equal to a height of the supporting piece.

15. The electronic device enclosure of claim 10, wherein the handle comprises a lifting piece in which a receiving opening is defined.

16. The electronic device enclosure of claim 15, wherein a connecting piece is connected to the lifting piece, and a securing piece is connected to the connecting piece, and the clasp protrudes on the securing piece.

17. The electronic device enclosure of claim 16, wherein the securing piece is parallel to the connecting piece.
